(19) United States
(12) Patent Application Publication
(10) Pub. No.: US 2010/0148798 A1
(43) Pub. Date: Jun. 17, 2010

(54) Apparatus and Method for Electrical Impedance Imaging

(76) Inventors: Wei Wang, Leicester (GB); Mengxing Tang, Leicester (GB)

Correspondence Address: WARE FRESSOLA VAN DER SLUYS & ADOLPHSON, LLP, BRADFORD GREEN, BUILDING 5, 755 MAIN STREET, P O BOX 224, MONROE, CT, 06468, US

(21) Appl. No.: 12/226,330

(22) PCT Filed: Mar. 16, 2007
(86) PCT No.: PCT/GB2007/000942

§ 371 Date: Sep. 19, 2009

(30) Foreign Application Priority Data
Apr. 13, 2006 (GB) 0607503.0

(51) Int. Cl. G01R 27/00

(52) U.S. Cl. 324/600

(57) ABSTRACT

An apparatus 10 for electrical impedance imaging of an object 12 comprises first and second electrode arrangements 14, 16 spaced apart to define an imaging region 24 therebetween. An object 12 to be imaged is locatable, in use, in the imaging region 24 so that impedance data can be collected from the object 12 using the first and second electrode arrangements 14, 16 to permit the construction of an impedance image of the object 12.

### FIELD OF THE INVENTION

Embodiments of the present invention relate to an apparatus and method for electrical impedance imaging. In particular, they relate to an apparatus and method for electrical impedance imaging of the female human breast to facilitate the detection of changes within the breast mass, including changes such as abnormalities, and other malignant changes, such as carcinomas, in the breast.

### BACKGROUND TO THE INVENTION

Electrical impedance mammography (EIM), or Electrical impedance imaging (EII), also referred to as electrical impedance tomography (EIT), electrical impedance scanner (EIS) and applied potential tomography (APT), is an imaging technique that is particularly used in medical applications.

The technique images the spatial distribution of electrical impedance inside an object, such as the human body. The technique is attractive as a medical diagnostic tool because it is non-invasive and does not use ionizing radiation, as in X-ray tomography, or the generation of strong, highly uniform magnetic fields, as in Magnetic Resonance Imaging (MRI).

Typically, a two-dimensional (2D) or three-dimensional (3D) array of evenly spaced electrodes is attached to the object to be imaged about the region of interest. Either input voltages are applied across a subset of ‘input’ electrodes and output electric currents are measured at ‘output’ electrodes, or input electric currents are applied between a subset of ‘input’ electrodes and output voltages are measured at ‘output’ electrodes or between pairs of output electrodes. For example, when a very small alternating electric current is applied between a subset of ‘input’ electrodes, the potential difference between output electrodes or between pairs of ‘output’ electrodes is measured. The current is then applied between a different subset of ‘input’ electrodes and the potential difference between the output electrodes or between pairs of ‘output’ electrodes is measured. An image can then be constructed using an appropriate image reconstruction technique,

Spatial variations revealed in electrical impedance images may result from variations in impedance between healthy and non-healthy tissues, variations in impedance between different tissues and organs, or variations in apparent impedance due to anisotropic effects resulting, for example, from muscle alignment.

Tissue or cellular changes associated with cancer cause significant localized variations in electrical impedance and can be imaged. WO 00/12005 discloses an example of an electrical impedance imaging apparatus that can be used to detect breast carcinomas or other carcinomas.

An object of this invention is to provide an improved apparatus and method for electrical impedance imaging of an object, and in particular for electrical impedance imaging of the female human breast.

### BRIEF DESCRIPTION OF THE INVENTION

According to a first aspect of the present invention, there is provided an apparatus for electrical impedance imaging of an object, the apparatus comprising first and second electrode arrangements spaced apart to define an imaging region therebetween, an object to be imaged being locatable, in use, in the imaging region so that impedance data can be collected from the object using the first and second electrode arrangements to permit the construction of an impedance image of the object.

Either one or both of the first and second electrode arrangements may be movable to at least partially compress an object located therebetween in the imaging region.

The apparatus may include a first support member on which the first electrode arrangement may be provided and may comprise a second support member on which the second electrode arrangement may be provided. Either one or both the first and second support members may be movable to vary the spacing between the first and second electrode arrangements.

In one embodiment of the invention, the first and second support members may be generally planar, and may be disposed generally parallel to each other.

The first and second electrode arrangements may each include a plurality of electrodes.

The first and second electrode arrangements may be operable in combination to collect impedance data from an object located in the imaging region, and this may advantageously permit the construction of an impedance image of the object. The first and second electrode arrangements may be operable in combination to collect multiple sets of impedance data from an object, and the multiple sets of collected impedance data may be used to construct an impedance image of the object.

The apparatus may include means for applying an input electrical signal via electrodes of the first electrode arrangement while measuring output electrical signals at electrodes of the second electrode arrangement.

The apparatus may include, means for applying an input electrical signal via electrodes of the second electrode arrangement while measuring output electrical signals at electrodes of the first electrode arrangement.

The apparatus may include means for applying an input electrical signal via electrodes of the first or second electrode arrangements while measuring output electrical signals at sets of electrodes in which one electrode of each set is provided by the first electrode arrangement and one electrode of each set is provided by the second electrode arrangement.

The apparatus may include means for applying an input electrical signal via a set of electrodes, in which one electrode of the set is provided by the first electrode arrangement and one electrode of the set is provided by the second electrode arrangement, while measuring output electrical signals at electrodes of the first or second electrode arrangements or at sets of electrodes in which one electrode of each set is provided by the first electrode arrangement and one electrode of each set is provided by the second electrode arrangement.

The apparatus may include means for applying an input electrical signal via a set of electrodes, in which one electrode of the set is provided by the first electrode arrangement and one electrode of the set is provided by the second electrode arrangement, while measuring output electrical signals at sets of electrodes provided by the first electrode arrangement and at sets of electrodes provided by the second electrode arrangement.

The apparatus may include means for applying an input electrical signal via electrodes of the first electrode arrangement while measuring output electrical signals at electrodes of the first electrode arrangement, and alternatively or additionally may include means for applying an input electrical signal via electrodes of the second electrode arrangement while measuring output electrical signals at electrodes of the second electrode arrangement.

This may provide two sets of electrical impedance data both of which may be used to construct an impedance image of the object.

The apparatus may include an electrically conductive medium for electrically coupling the electrodes of the first electrode arrangement and/or the second electrode arrangement to an object located in the imaging region so that the electrodes do not contact the object but are electrically coupled thereto via the electrically conductive medium.

The electrically conductive medium may comprise ions, and may be a fluid or may alternatively be a semi-solid substance, such as a gel.

The conductivity of the electrically conductive medium may be carefully controlled by controlling the concentration of ions. This provides the advantage that an optimised impedance image of an object in the imaging region can be obtained. For example, the conductivity of the electrically conductive medium may be controlled so that it is equal to the conductivity of the boundary layer of an object in the imaging region. The ions may include Group I metal ions such as Na+. The ions may include Group VII halide ions such as Cl−.

An advantage of using an electrically conductive medium comprising ions is that the conductive mechanism between the electrode and the object is ‘electrode-ions-object’ based on “sizeless” ions. This conduction mechanism provides a “perfect” contact between the electrode and the object with known “half-cell” potentials once the electrode material is chosen. As the conduction mechanism is not a typical “electrode-skin interface” it does not suffer the disadvantages associated with any “contact” based “electrode-skin interface”, namely an unknown effective contact area which provides an unknown contact impedance including associated capacitance from the “electrode-skin interface”. The electrode-ion-object conduction mechanism is not dependent upon the contact area between the electrode and the object. This allows the use of smaller electrodes, which allows a greater number of electrodes to be used to image an object, which in turn provides greater resolution in the image produced.

According to a second aspect of the present invention, there is provided a method for electrical impedance imaging of an object using a first electrode arrangement and a second electrode arrangement spaced from the first electrode arrangement to define an imaging region between the first and second electrode arrangements, the method including locating an object to be imaged in the imaging region and collecting electrical impedance data from the object using the first and second electrode arrangements.

The first and second electrode arrangements may each include a plurality of electrodes.

The step of collecting electrical impedance data may comprise applying an input electrical signal via electrodes of the first electrode arrangement while measuring output electrical signals at electrodes of the second electrode arrangement.

The step of collecting electrical impedance data may alternatively or additionally comprise applying an input electrical signal via electrodes of the second electrode arrangement while measuring output electrical signals at electrodes of the first electrode arrangement.

The step of collecting electrical impedance data may comprise applying an input electrical signal via electrodes of the first or second electrode arrangements while measuring output electrical signals at sets of electrodes in which one electrode of each set is provided by the first electrode arrangement and one electrode of each set is provided by the second electrode arrangement.

The step of collecting electrical impedance data may comprise applying an input electrical signal via a set of electrodes, in which one electrode of the set is provided by the first electrode arrangement and one electrode of the set is provided by the second electrode arrangement, while measuring output electrical signals at electrodes of the first or second electrode arrangements or at sets of electrodes in which one electrode of each set is provided by the first electrode arrangement and one electrode of each set is provided by the second electrode arrangement.

The step of collecting electrical impedance data may comprise applying an input electrical signal via a set of electrodes, in which one electrode of the set is provided by the first electrode arrangement and one electrode of the set is provided by the second electrode arrangement, while measuring output electrical signals at sets of electrodes provided by the first electrode arrangement and at sets of electrodes provided by the second electrode arrangement.

The step of collecting electrical impedance data may comprise applying an input electrical signal via electrodes of the first electrode arrangement while measuring output electrical signals at electrodes of the first electrode arrangement and may alternatively or additionally comprise applying an input electrical signal via electrodes of the second electrode arrangement while measuring output electrical signals at electrodes of the second electrode arrangement.

The step of collecting electrical impedance data may comprise applying an input electrical signal via a set of electrodes of the first electrode arrangement while measuring output electrical signals at the same or other electrodes of the first electrode arrangement.

The step of collecting electrical impedance data may comprise applying an input electrical signal via a set of electrodes of the second electrode arrangement while measuring output electrical signals at the same or other electrodes of the second electrode arrangement.

The step of collecting electrical impedance data may comprises applying an input electrical signal between an electrode of the first electrode arrangement and an electrode of the second electrode arrangement, while measuring an output electrical signal between electrodes of the first electrode arrangement and/or between electrodes of the second electrode arrangement and/or between electrodes of the opposing first and second electrode arrangements.

The first and/or second electrode arrangements may be movable and the method may comprise at least partially compressing an object to be imaged in the imaging region by moving either one or both of the first and second electrode arrangements.

The method may comprise electrically coupling the object to the first and/or second electrode arrangements via an electrically conductive medium so that there is no contact between the respective first and/or second electrode arrangement and the object.

The method may further comprise constructing an image of the object located in the imaging region based on the electrical impedance data collected from the object using the first and second electrode arrangements.

The method may be performed using the apparatus according to the first aspect of the invention.

### BRIEF DESCRIPTION OF THE DRAWINGS

For a better understanding of the present invention, reference will now be made by way of example only to the accompanying drawings in which:

FIG. 1 is a diagrammatic perspective view of one embodiment of an apparatus for electrical impedance imaging of an object;

FIG. 2 is a diagrammatic cross-sectional side view through the part of apparatus of FIG. 1 and an object being imaged;

FIG. 3 is diagrammatic cross-sectional top view of the apparatus of FIG. 1; and

FIGS. 4 and 5 are diagrammatic views, similar to FIGS. 2 and 3 respectively, of another embodiment of an apparatus for electrical impedance imaging of an object.

### DETAILED DESCRIPTION OF EMBODIMENTS OF THE INVENTION

Referring to the drawings, there is shown generally and diagrammatically apparatus 10, 110 for electrical impedance imaging of an object 12. The apparatus 10, 110 described in the following paragraphs has been adapted for use in electrical impedance imaging of the female human breast.

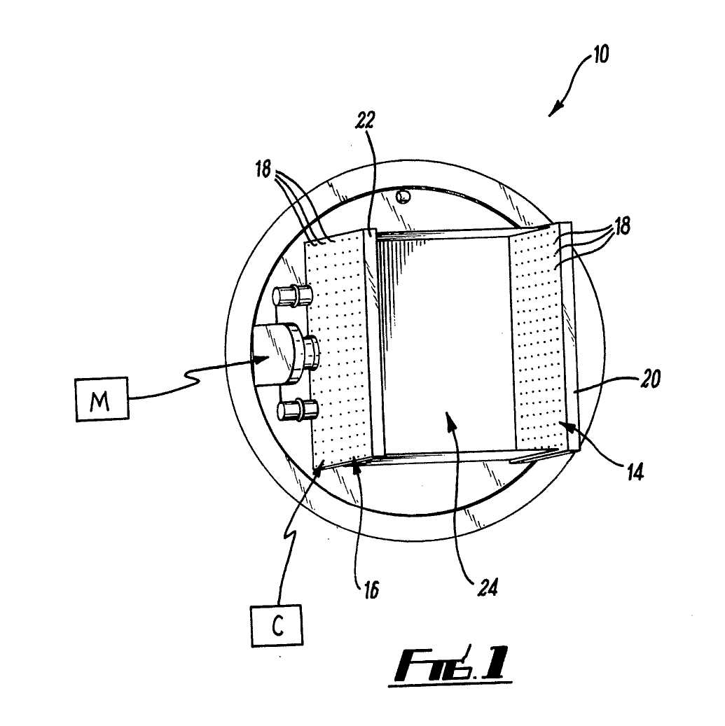

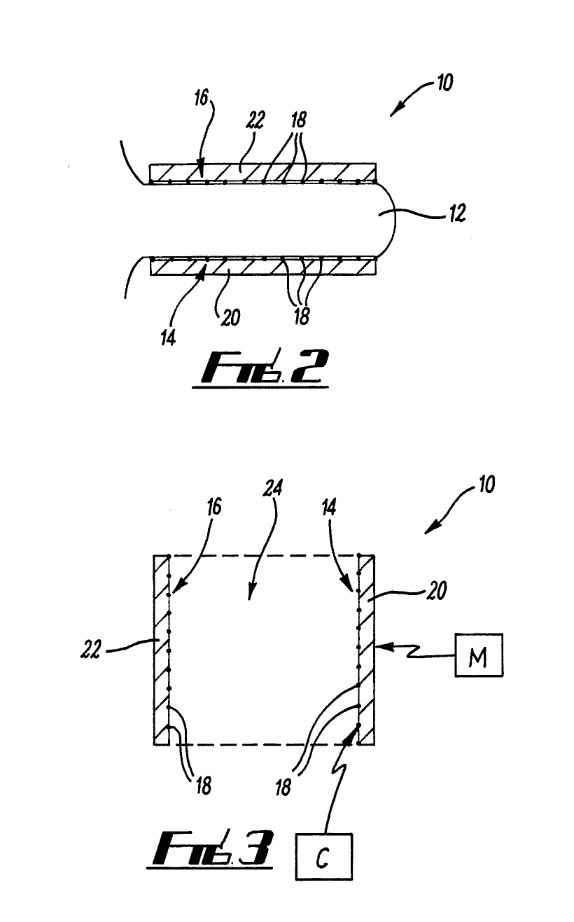

Referring to FIGS. 1 to 3, one embodiment of the apparatus 10 includes first and second electrode arrangements 14, 16, each of which comprises a plurality of electrodes 18. The electrodes 18 of the first electrode arrangement 14 are provided on a first support member 20 and the electrodes 18 of the second electrode arrangement 16 are provided on a second support member 22. In the illustrated embodiment, the first and second support members 20, 22 are in the form of generally planar panels disposed substantially parallel to each other.

The first and second electrode arrangements 14, 16 are spaced apart and define therebetween an imaging region 24 in which the object 12 to be imaged is locatable. Either one of the first and second support members 20, 22, or both of the first and second support members 20, 22, are movable to enable the spacing between the first and second electrode arrangements 14, 16, in other words the effective size of the imaging region 24, to be varied.

When an object 12 to be imaged is initially located in the imaging region 24, the first and second support members 20, 22 are spaced apart by a sufficient distance to readily accommodate the object 12. The first and second support members 20, 22 are then moved towards each other to decrease the spacing between the first and second electrode arrangements 14, 16, and as a consequence the object 12 is at least partially compressed. This at least partial compression of the object 12 between the first and second electrode arrangements 14, 16 is an advantageous feature of the invention, as will be explained in more detail later in the specification.

The apparatus 10 includes a drive mechanism M to move the first and second support members 20, 22 and thereby vary the spacing between the first and second electrode arrangements 14, 16. A pressure sensing arrangement (not shown) may be coupled to the drive mechanism M via a feedback control circuit so that the object 12 is not compressed by an excessive amount. This is particularly important when the object 12 being imaged is a female human breast since excessive compression will result in discomfort for the female patient.

In use, as indicated above, an object 12 to be imaged is located in the imaging region 24 between the first and second electrode arrangements 14, 16, and the drive mechanism M is actuated to move the first and second support members 20, 22 together, thereby at least partially compressing the object 12 between the first and second electrode arrangements 14, 16. The amount of compression is detected by the pressure sensing arrangement and is relayed via the feedback control circuit so that the drive mechanism M is deactivated before the object 12 is unduly compressed.

After the object 12 has been at least partially compressed, impedance data can be collected from the object 12 to permit the construction of an impedance image, as will now be explained.

Each of the electrodes 18 of the first and second electrode arrangements 14, 16 are fixed on the respective first and second support members 20, 22 in a known position, and the electrodes 18 of each of the first and second electrode arrangements 14, 16 are arranged as a spaced regular array. The electrodes 18 of both the first and second electrode arrangements 14, 16 are connected to imaging control circuitry C which comprises electrical signal generating circuitry for passing an input electrical signal in the form of an input electric current via a set of electrodes 18 while measuring an output electrical signal in the form of output potential differences at the same and/or other electrodes 18. The applied input electric current typically comprises a plurality of different frequencies and at least some frequencies above 1 MHz. Frequencies from 100 Hz to above 1 MHz (preferably 10 MHz) have been used with the frequency bandwidth exceeding 1 MHz.

In other embodiments, the electrical signal generating circuitry provides an input electrical signal in the form of an input potential difference across a set of electrodes 18 while measuring output electrical signals in the form of output electric currents at the same and/or other electrodes 18. The applied input potential difference typically comprises a plurality of different frequencies and at least some frequencies above 1 MHz.

The total impedance of a tissue or group of cells can be modeled as a parallel intra-cellular impedance and a parallel extra-cellular impedance. The intra-cellular impedance can be modeled as a series connection of a capacitance Cᵢ and a resistance Rᵢ. The extra-cellular impedance can be modeled as a resistance Rₓ. At lower frequencies, the total impedance is dominated by Rₓ and at higher frequencies the total impedance is dominated by Rᵢ//Rₓ. The frequency response is sensitive to variations in Cᵢ, Rᵢ and Rₓ and can be used to identify the presence of abnormal tissue.

The measured output electrical signals are converted from analogue to digital signals and are processed to produce a 2D, a 2.5D or a 3D image of the breast. Suitable algorithms such as the Filtered Back Projection algorithm or the modified Newton-Raphson algorithm are employed for this purpose. Images may also be obtained by either a direct spatial mapping of the measured data acquired using the electrodes 18a or by a spatial mapping of filtered data. In all cases, any abnormality of body tissue in the breast, such as a carcinoma, will typically appear as a contrast region in the image.

Advantageously, input electric signals can be applied in different ways and the resulting output electric signals can be measured in different ways, using the apparatus 10, to enable the collection of impedance data from the object 12 being imaged and thus the construction of an impedance image of the object 12. Some non-limiting examples are set out below, it being understood that other examples are within the scope of the claims.

### Example A

The imaging control circuitry C passes an input electrical signal into the object 12 via a first set of two input electrodes 18 of the first electrode arrangement 14 while measuring output electrical signals at output electrodes 18 of the first electrode arrangement 14. This process can be repeated for multiple sets of input electrodes 18 and multiple sets of output electrodes 18 of the first electrode arrangement 14 to enable the collection of a first set of impedance data.

The imaging control circuitry C thereafter passes an input electrical signal into the object 12 via a first set of two input electrodes 18 of the second electrode arrangement 16 while measuring output electrical signals at output electrodes 18 of the second electrode arrangement 16. This process can be repeated for multiple sets of input electrodes 18 and multiple sets of output electrodes 18 of the second electrode arrangement 16 to enable the collection of a second set of impedance data.

In this example, the first and second electrode arrangements 14, 16 are thus used to collect first and second sets of impedance data from the object 12, and both the first and second sets of collected impedance data are then used to construct an impedance image of the object 12.

### Example B

The imaging control circuitry C passes an input electrical signal into the object 12 via a first set of two input electrodes 18 of the first electrode arrangement 14 while measuring output electrical signals at output electrodes 18 of the second electrode arrangement 16. This process can be repeated for multiple sets of input electrodes 18 of the first electrode arrangement 14 and for multiple sets of output electrodes 18 of the second electrode arrangement 16 to enable the collection of a set of impedance data.

The set of collected impedance data can then be used to construct an impedance image of the object 12.

### Example C

The imaging control circuitry C passes an input electrical signal into the object 12 via a first set of two input electrodes 18 of the second electrode arrangement 16 while measuring output electrical signals at output electrodes 18 of the first electrode arrangement 14. This process can be repeated for multiple sets of input electrodes 18 of the second electrode arrangement 16 and for multiple sets of output electrodes 18 of the first electrode arrangement 14 to enable the collection of a set of impedance data.

The set of collected impedance data can then be used to construct an impedance image of the object 12.

### Example D

In this example, a first set of impedance data can be collected from the object 12 according to ‘Example B’ and a second set of impedance data can be collected from the object 12 according to ‘Example C’.

Both the first and second sets of collected impedance data can then be used to construct an impedance image of the object 12.

### Example E

The imaging control circuitry C passes an input electrical signal into the object 12 via sets of two input electrodes 18, a first of said input electrodes 18 being provided by the first electrode arrangement 14 and a second of said input electrodes 18 being provided by the second electrode arrangement 16.

The imaging control circuitry C simultaneously measures output electrical signals at sets of output electrodes 18 to enable the collection of impedance data, each set of output electrodes 18 being defined by at least an output electrode 18 of the first electrode arrangement 14 and at least an output electrode 18 of the second electrode arrangement 16.

The set of collected impedance data can then be used to construct an impedance image of the object 12.

### Example F

The imaging control circuitry C passes an input electrical signal into the object 12 via sets of two input electrodes 18, a first of said input electrodes 18 being provided by the first electrode arrangement 14 and a second of said input electrodes 18 being provided by the second electrode arrangement 16.

The imaging control circuitry C simultaneously measures output electrical signals at sets of output electrodes 18 to enable the collection of impedance data, each set of output electrodes 18 being defined by output electrodes 18 of the first electrode arrangement 14.

The set of collected impedance data can then be used to construct an impedance image of the object 12.

### Example G

The imaging control circuitry C passes an input electrical signal into the object 12 via sets of two input electrodes 18, a first of said input electrodes 18 being provided by the first electrode arrangement 14 and a second of said input electrodes 18 being provided by the second electrode arrangement 16.

The imaging control circuitry C simultaneously measures output electrical signals at sets of output electrodes 18 to enable the collection of impedance data, each set of output electrodes 18 being defined by output electrodes 18 of the second electrode arrangement 16.

The set of collected impedance data can then be used to construct an impedance image of the object 12.

### Example H

In this example, multiple sets of impedance data can be collected from the object 12 according to any combination of ‘Example E’, ‘Example F’ and ‘Example G’, and the multiple sets of collected impedance data can then be used to construct an impedance image of the object 12.

All of the examples set out above utilise some combination of the first and second electrode arrangements 14, 16 to collect impedance data from an object 12, based on the electrical signals inputted via, and measured using, the electrodes 18. In practice, it may be possible to use any suitable combination of the examples set out above to collect multiple sets of impedance data from an object 12, and thereafter construct an impedance image of the object 12 based on the multiple sets of collected impedance data.

In the Examples ‘A’ to ‘H’ described above the input electrical signal may be an electric current and the measured output electrical signal may be a potential difference, or alternatively the input electrical signal may be a potential difference and the measured output electrical signal may be an electric current.

By utilising first and second electrode arrangements 14, 16 to collect impedance data from an object 12, more reliable imaging can be achieved using the apparatus 10.

For example, each of the first and second electrode arrangements 14, 16 may be able to detect abnormalities within an object 12 up to a distance of 4 to 5 cm away from the respective arrangement. Thus, when the two electrode arrangements 14, 16 are used to image an object 12 located in the imaging region 24, the detection of abnormalities in objects that are up to approximately 8 to 10 cm in thickness, when at least partially compressed, is possible. The detection distance using the apparatus 10 is thus doubled relative to the detection distance of an apparatus employing a single electrode arrangement. This is advantageous when the object is a female human breast, as it allows a reliable impedance image of a large breast to be obtained, without the need for significant compression of the breast. As discussed above, significant compression of the female human breast is undesirable as this creates discomfort for the female patient.

Another advantage of at least partially compressing a female human breast between the first and second electrode arrangements 14, 16 arises specifically in relation to the detection of breast cancer using the apparatus 10. This is because the images of an at least partially compressed human female breast that can be obtained using the apparatus 10 are very similar to, and can therefore be correlated with and compared to, images obtained via X-ray mammography, which is the current standard breast cancer screening technique.

In the case of smaller objects, such as smaller female human breasts which can be at least partially compressed without significant discomfort for the patient so that the effective thickness is less than approximately 8 to 10 cm, an impedance image having higher resolution can be obtained using the apparatus 10. This is because there will be an overlap in the detection range of each of the first and second electrode arrangements 14, 16, and, in this overlapping detection range, the detection sensitivity will be greater due to the ability of both of the first and second electrode arrangements 14, 16 to collect impedance data. Thus, a high resolution image of a central or core region of the object 12 can be obtained.

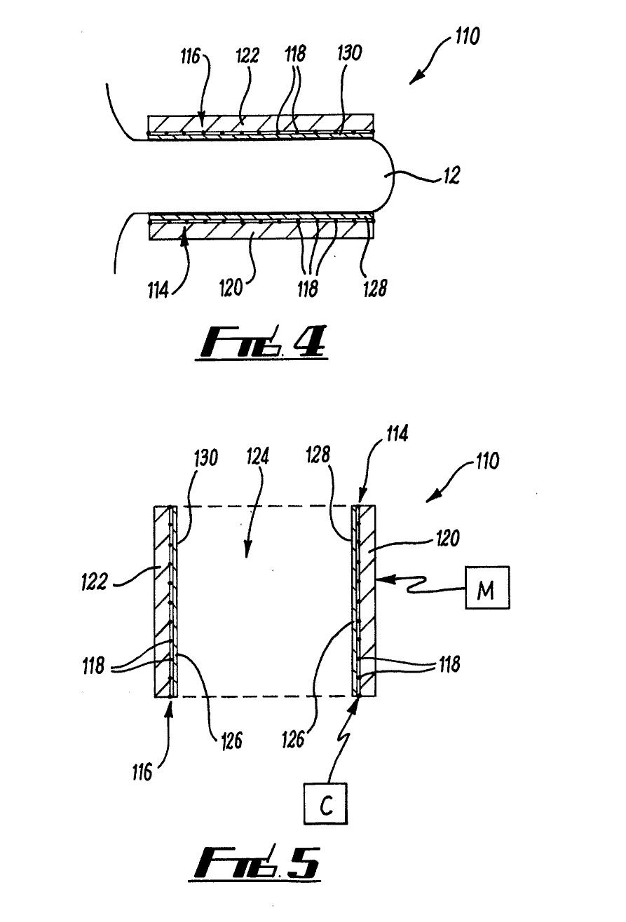

FIGS. 4 and 5 show another embodiment of an apparatus 110 for electrical impedance imaging of an object 12. The apparatus 110 of FIGS. 4 and 5 is very similar to the apparatus 10 of FIGS. 1 to 3, and corresponding components are therefore designated using the same reference numerals, prefixed with the number ‘1’.

As best seen in FIG. 4, in the apparatus 110, the object 12 being imaged does not contact the electrodes 118 of the first and second electrode arrangements 114, 116, the apparatus 110 including an electrically conductive medium 126 to electrically couple the object 12 to the electrodes 118. Further details about the use of an electrically conductive medium 126 are set out in the Applicant's co-pending UK patent application no. 0516158.3 entitled ‘An apparatus and method for ‘non-contact’ electrical impedance imaging’, the contents of which are incorporated herein in their entirety.

In the embodiment illustrated in FIGS. 4 and 5, the electrically conductive medium 126 comprises first and second generally planar electrically conductive members 128, 130, each in the form of a semi-solid substance such as a gel pad, the semi-solid substance containing ions and typically being saline based.

As already mentioned above, an advantage of employing an electrically conductive medium 126 between the object 12 and the electrodes 118 of the first and second electrode arrangements 114, 116 is that it substantially standardises the impedance between each electrode 118 and the object 12 and achieves a “perfect” contact between each electrode 118 and the object 12 based on “sizeless” ions within the electrically conductive medium 126. This allows for more reliable imaging.

Although embodiments of the present invention have been described in the preceding paragraphs with reference to various examples, it should be appreciated that modifications to the examples given can be made without departing from the scope of the invention, as claimed.

For example, the apparatus and method may be used to construct an impedance image of an object other than a female human breast, for example another part of the human anatomy.

The electrodes 18 may be mounted on the first and second support members 20, 22 as a non-regular spaced array. For example, the electrodes 18 may be mounted on the first and second support members 20, 22 so that there is greater separation between adjacent electrodes 18 towards a periphery of each of the first and second support members 20, 22 than in a central region of the first and second support members 20, 22 where changes within a female human breast are more likely to occur and be detected.

The support members 20, 22 may be of a configuration other than planar. For example, they may be shaped or contoured to match the shape or contours of the object 12 being imaged. In the case where the object 12 is a female human breast, the support members 20, 22 may be curved. In this case, it will be readily appreciated that the first and second support members 20, 22 may not be parallel to each other.

The electrically conductive medium 126 may be an electrically conductive fluid, and the first and second electrode arrangements 114, 116 and the object 12 being imaged may be immersed in the electrically conductive fluid.

Whilst endeavoring in the foregoing specification to draw attention to those features of the invention believed to be of particular importance it should be understood that the Applicant claims protection in respect of any patentable feature or combination of features hereinbefore referred to and/or shown in the drawings whether or not particular emphasis has been placed thereon.

What is claimed is:

1. An apparatus comprising: first and second electrode arrangements spaced apart to define an imaging region therebetween, an object to be imaged being locatable, in use, in the imaging region so that electrical impedance data can be collected from the object using the first and second electrode arrangements to permit the construction of an impedance image of the object.

2. The apparatus according to claim 1, wherein the first and/or second electrode arrangements are movable to at least partially compress an object located therebetween in the imaging region.

3. The apparatus according to claim 1, wherein the apparatus includes a first support member on which the first electrode arrangement is provided and a second support member on which the second electrode arrangement is provided.

4. The apparatus according to claim 3, wherein either one or both the first and second support members are movable to vary the spacing between the first and second electrode arrangements.

5. The apparatus according to claim 3, wherein the first and second support members are generally planar.

6. The apparatus according to claim 5, wherein the first and second planar support members are generally parallel to each other.

7. The apparatus according to claim 1, wherein the first and second electrode arrangements each include a plurality of electrodes.

8. The apparatus according to claim 1, wherein the first and second electrode arrangements are operable in combination to collect impedance data from an object located in the imaging region to permit the construction of an impedance image of the object.

9. The apparatus according to claim 7, wherein the apparatus includes means for applying an input electrical signal via electrodes of the first electrode arrangement while measuring output electrical signals at electrodes of the second electrode arrangement.

10. The apparatus according to claim 7, wherein the apparatus includes means for applying an input electrical signal via electrodes of the second electrode arrangement while measuring output electrical signals at electrodes of the first electrode arrangement.

11. The apparatus according to claim 7, wherein the apparatus includes means for applying an input electrical signal via electrodes of the first or second electrode arrangements while measuring output electrical signals at sets of electrodes in which one electrode of each set is provided by the first electrode arrangement and one electrode of each set is provided by the second electrode arrangement.

12. The apparatus according to claim 7, wherein the apparatus includes means for applying an input electrical signal via a set of electrodes, in which one electrode of the set is provided by the first electrode arrangement and one electrode of the set is provided by the second electrode arrangement, while measuring output electrical signals at electrodes of the first or second electrode arrangements or at sets of electrodes in which one electrode of each set is provided by the first electrode arrangement and one electrode of each set is provided by the second electrode arrangement.

13. The apparatus according to claim 7, wherein the apparatus includes means for applying an input electrical signal via a set of electrodes, in which one electrode of the set is provided by the first electrode arrangement and one electrode of the set is provided by the second electrode arrangement, while measuring output electrical signals at sets of electrodes provided by the first electrode arrangement and at sets of electrodes provided by the second electrode arrangement.

14. The apparatus according to claim 7, wherein the apparatus includes means for applying an input electrical signal via electrodes of the first electrode arrangement while measuring output electrical signals at electrodes of the first electrode arrangement, and means for applying an input electrical signal via electrodes of the second electrode arrangement while measuring output electrical signals at electrodes of the second electrode arrangement.

15. The apparatus according to claim 1, wherein the apparatus includes an electrically conductive medium for electrically coupling the electrodes of the first electrode arrangement and/or the second electrode arrangement to an object located in the imaging region so that the electrodes do not contact the object but are electrically coupled thereto via the electrically conductive medium.

16. Apparatus according to claim 15, wherein the electrically conductive medium is a fluid or a semi-solid substance.

17. (canceled)

18. A method comprising:
locating an object to be imaged in an imaging region between a first electrode arrangement and a second electrode arrangement spaced from the first electrode arrangement, and
collecting electrical impedance data from the object using the first and second electrode arrangements.

19. The method according to claim 18, wherein the first and second electrode arrangements each include a plurality of electrodes.

20. A method according to claim 19, wherein the collecting electrical impedance data comprises applying an input electrical signal via electrodes of the first electrode arrangement while measuring output electrical signals at electrodes of the second electrode arrangement.

21. The method according to claim 19, wherein the collecting electrical impedance data comprises applying an input electrical signal via electrodes of the second electrode arrangement while measuring output electrical signals at electrodes of the first electrode arrangement.

22. The method according to claim 19, wherein the collecting electrical impedance data comprises applying an input electrical signal via electrodes of the first or second electrode arrangements while measuring output electrical signals at sets of electrodes in which one electrode of each set is provided by the first electrode arrangement and one electrode of each set is provided by the second electrode arrangement.

23. The method according to claim 19, wherein the collecting electrical impedance data comprises applying an input electrical signal via a set of electrodes, in which one electrode of the set is provided by the first electrode arrangement and one electrode of the set is provided by the second electrode arrangement, while measuring output electrical signals at electrodes of the first or second electrode arrangements or at sets of electrodes in which one electrode of each set is provided by the first electrode arrangement and one electrode of each set is provided by the second electrode arrangement.

24. The method according to claim 19, wherein the collecting electrical impedance data comprises applying an input electrical signal via a set of electrodes, in which one electrode of the set is provided by the first electrode arrangement and one electrode of the set is provided by the second electrode arrangement, while measuring output electrical signals at sets of electrodes provided by the first electrode arrangement and at sets of electrodes provided by the second electrode arrangement.

25. The method according to claim 19, wherein the collecting electrical impedance data comprises applying an input electrical signal via electrodes of the first electrode arrangement while measuring output electrical signals at electrodes of the first electrode arrangement, and applying an input electrical signal via electrodes of the second electrode arrangement while measuring output electrical signals at electrodes of the second electrode arrangement.

26. The method according to claim 18, wherein the first and/or second electrode arrangements are movable and the method comprises at least partially compressing an object to be imaged in the imaging region by moving either one or both of the first and second electrode arrangements.

27. The method according to claim 18, wherein the method comprises electrically coupling the object to the first and/or second electrode arrangements via an electrically conductive medium so that there is no contact between the respective first and/or second electrode arrangement and the object.

28. The method according to claim 18, further comprising constructing an image of the object in the imaging region based on the collected electrical impedance data.

29. The method according to claim 18, wherein the method is performed using first and second electrode arrangements spaced apart to define an imaging region therebetween, an object to be imaged being locatable, in use, in the imaging region so that electrical impedance data can be collected from the object using the first and second electrode arrangements to permit the construction of an impedance image of the object.

30. (canceled)
